(19) United States
(12) Patent Application Publication
(10) Pub. No.: US 2002/0136052 A1
(43) Pub. Date: Sep. 26, 2002

(54) Programmable memory device

(76) Inventor: Henry Fang, Lo-Tung town (TW)

Correspondence Address: J.C. Patents, Suite 250, 4 Venture, Irvine, CA, 92618, US

(21) Appl. No.: 10/121,110

(22) Filed: Apr. 9, 2002

Related U.S. Application Data
(62) Division of application No. 09/815,514, filed on Mar. 23, 2001.

(51) Int. Cl. G11C 11/24

(52) U.S. Cl. 365/149

(57) ABSTRACT

A DRAM memory device capable of volatile, and non-volatile memory functions is provided. To achieve non-volatile memory functions a programming voltage is applied to DRAM memory cells consisting of a wordline, a bitline, a transistor, and a capacitive storage device. The programming voltage permanently alters the voltage leakage characteristics of the capacitive storage device. The DRAM memory device can then be read the memory cells by determining which cells have greater voltage leakage characteristics.

### FIELD OF THE INVENTION

The present invention relates to a programmable memory device, and more particularly, to the programming of a dynamic random access memory.

### BACKGROUND OF INVENTION

In today's society electronics devices that require data storage are becoming increasingly common. Most data processing devices will consist of two types of memory storage devices, referred to as volatile memory or RAM, and non-volatile memory or ROM. Volatile memory will lose its stored data when power is removed from the device, while non-volatile memory will retain its data for extended periods of time after power has been removed from the device. Typically in many electronic devices both types of memory devices will exist within a device, non-volatile memory used for storing needed long-term data that rarely changes, and volatile memory for storing data that is only required for a short-time.

The most common type of volatile memory device used is the dynamic random access memory or DRAM. DRAM's are a preferred choice due to their relatively low cost, high storage capacity, and small size. Advances in semiconductor processes have allowed DRAM to become increasingly smaller, and cheaper.

DRAM arrays are manufactured by reproducing millions of identical memory circuits which are composed of a plurality of memory cells, wordlines, and bitlines. The bitlines lay orthogonal to the wordlines, and the memory cells are located adjacent to the crossovers of the wordlines, and the bitlines. Conventional DRAM memory cells consist of a single transistor architecture wherein the memory cell comprises a storage capacitor having a first terminal connected to a reference voltage, such as V_{REF}, and to a second terminal connected to a pass gate transistor which is usually a field effect transistor.

Data is stored in each memory cell as a charge level on a storage capacitor. The storage capacitor will over time experience leakage current either from the storage capacitor or from the pass gate transistor. This leakage current over time will degrade a voltage level, particularly a high voltage level, stored on the storage capacitor. The voltage level on the storage capacitor must therefore be periodically refreshed in order to prevent decay of the data stored in the memory cell.

Conventional DRAM's typically use a current sense amplifier to sense whether the value in a selected memory cell is a logic one or zero. For reading data, the sense amplifier will detect a small differential voltage between a stored voltage and a reference voltage. The sense amplifier can then further increase the voltage differential to full logic levels.

When non-volatile memory is required most devices use a type of PROM or mask ROM. These types of memories have the limitations however of being physically larger in size than modern DRAM memories, and are more expensive. The methods of manufacturing typical ROM memories and RAM memories are vastly different and therefore quite difficult to manufacture on a single device. Another method used is to purposely short the circuits of a DRAM memory cell, and read the cell using conventional sensing schemes in order to provide mask ROM functions. These methods have the limitations however of needing to be implemented during the manufacturing process. Therefore a need exists for a memory device that can realize the functions of volatile, and programmable non-volatile memories.

### SUMMARY OF THE INVENTION

The present invention implements a memory device that allows a dynamic random access memory (DRAM) to realize the function of a volatile memory, and a programmable non-volatile memory. It is a further objective of the invention to provide a method for programming a dynamic random access memory (DRAM). It is yet a further objective of the invention to provide a method for operating, and reading a programmed dynamic random access memory (DRAM). By allowing DRAM to realize the functions of volatile, and non-volatile memory the invention incorporates all the advantages of DRAM memory including small size, low-cost, and high storage capability.

The invention discloses a dynamic random access memory wherein individual memory cells can be programmed by sending a programming voltage to a memory cell thereby affecting its dielectric layer, and changing its capacitive storage characteristics. The altered storage device will thereafter have a permanent current leakage characteristic that will define the cell as being programmed. This ability to program the device after manufacture is a definite advantage over prior devices.

The device will determine which cells are programmed by charging all memory cells and allowing a time for the leaky cells to discharge. A memory cell that has had a programmed voltage applied to it will leak voltage at a greater rate than a non-programmed memory cell. The device can then read the DRAM device to determine the programmed data sequence. The device will periodically refresh the memory cells to maintain a desired stored value.

These and other features, which characterize the invention, are set forth in the claims annexed hereto and forming a further part hereof. However, for a better understanding of the invention, and of the advantages and objectives attained through its use, reference should be made to the drawings, and to the accompanying descriptive matter, in which there is described exemplary embodiments of the invention.

### BRIEF DESCRIPTION OF THE DRAWINGS

FIG. 1 is a block diagram showing a general structure of a DRAM and accompanying circuitry.

FIG. 2 is a circuit diagram of a conventional DRAM memory cell.

FIG. 3 is a timing diagram showing a method of programming according to a preferred embodiment.

FIG. 4 is a flowchart showing a method of operating a programmable DRAM according to a preferred embodiment.

### DETAILED DESCRIPTION

The invention as described herein provides a method for creating, reading, and operating a programmable dynamic random access memory (DRAM). In the following detailed description of the preferred embodiments, reference is made to the accompanying drawings that form a part hereof, and in which is shown by way of illustration specific preferred embodiments in which the invention may be practiced. The preferred embodiments are described in sufficient detail to enable these skilled in the art to practice the invention, and it is to be understood that other embodiments may be utilized and that logical, changes may be made without departing from the spirit and scope of the present invention. The following detailed description is, therefore, not to be taken in a limiting sense, and the scope of the present invention is defined only be the appended claims.

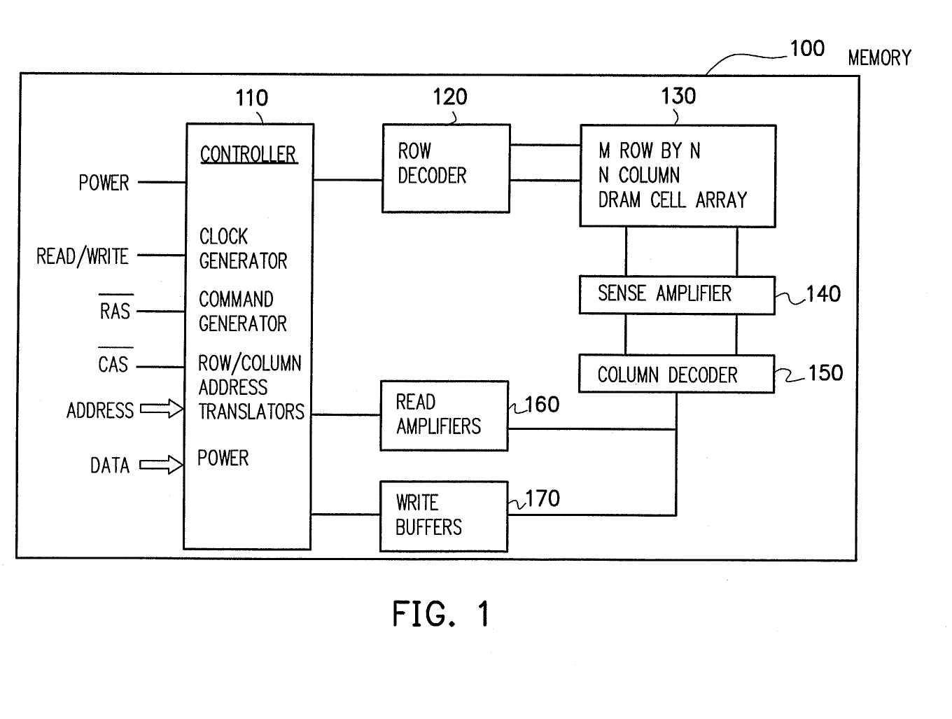

FIG. 1 shows a memory 100, composed of a DRAM M×N memory cell array 130, a controller 110, a row decoder 120, a plurality of sense amplifiers 140, a column decoder 150, a plurality of read amplifiers 160, and a plurality of write buffers 170. The controller 110 is composed of a clock generator, command generator, row/column address translator, and power. A DRAM array 130 will consist of a plurality of identical memory cells arranged in M rows by N columns. As well known in the art typically the DRAM array is divided into a plurality of memory banks. Each bank is then accessed by using row decoders 120 and columns decoders 130. The circuit receives control signal and clocks from an external source such as a CPU to the controller 110. Although not illustrated herein, the principles of the invention may also be embodied into numerous types of data manipulation devices which are well known to those skilled in the art.

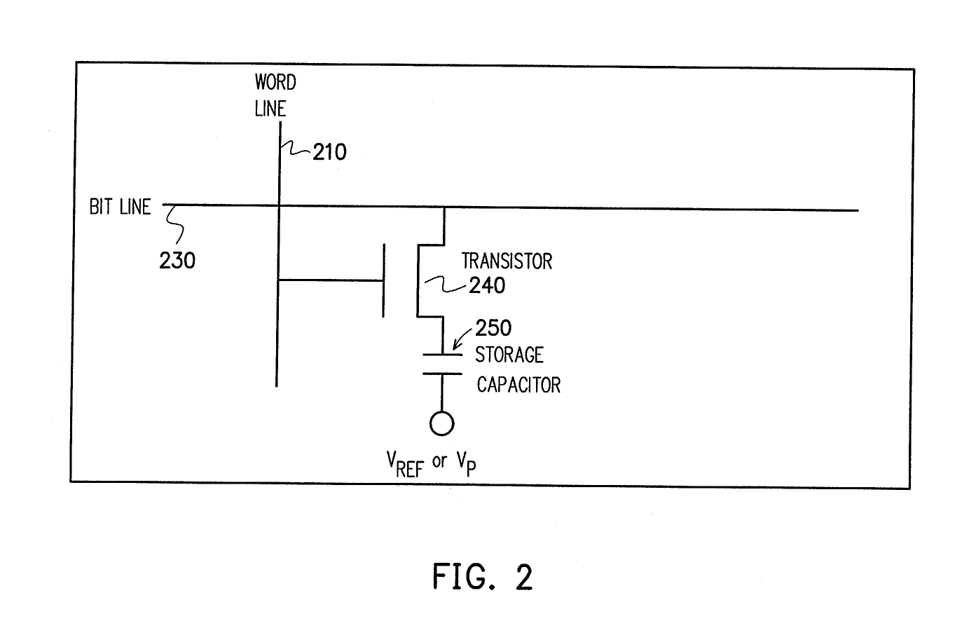

FIG. 2 shows a conventional DRAM memory cell 200 that is consistent with the invention that consists of a single transistor architecture wherein the memory cell comprises a storage capacitor 250, having a first terminal connected to a reference voltage, such as V_{REF}, and to a second terminal connected to a pass gate transistor which is usually a field effect transistor 240. The reference voltage V_{REF} is typically assigned to half of the power supply voltage V_{DD}. The pass gate transistor 240 serves to transport a charge to a storage capacitor 250, and also to read a capacitor to determine its charge level. The gate electrode of the pass gate transistor is tied to the word line decode signal 210, and the drain electrode is connected to the bitline 230. Typically the pass gate transistor 240 is a N-Channel field effect transistor. When a voltage representing a high or low logic level is stored onto the storage capacitor 250 of the memory cell, a voltage level is provided to the selected word line 210, and the gate electrode of the memory cell pass gate transistor 240 to activate the corresponding memory cell. A charge will then transfer between a storage capacitor 250, and a corresponding bitline 230 through the pass gate transistor 240. The operation and implementation of non-volatile memory devices is well know to those skilled in the art, and therefore will not be described in greater detail herein.

The present invention identifies a methodology to program DRAM cells by exposing selected cells to a programming voltage thereby altering their cell leakage characteristics. This can allow a DRAM device to realize the functions of volatile, and non-volatile memory within the same device. The programming voltage V_{P} is a voltage high enough to stress, and break down the dielectric layer as to permanently reduce the capacitive storage ability of the dielectric layer. The voltage V_{P} can be generated from a variety of sources including internal, and external means. The exact value of V_{P} is determined by such factors as the thickness, type of dielectric, and structure of the storage capacitor as well known in the art. The voltage can be applied to the memory cell at its full magnitude, or as a gradually increasing voltage to a magnitude of V_{P} To use an example, for a 50A thick ONO dielectric the programming voltage or V_{P} is around 6 to 7 volts. The programming voltage V_{P} is applied to a plate electrode of a storage capacitor for a specified time period. The time period will vary depending upon factors such the thickness and type of dielectric, structure of the storage capacitor, and degree of dielectric breakdown required. It should be noted that the programming voltage can be applied in one constant time period or in a series of time periods. Both the time period(s), and value of the programming voltage on a specific device can be determined by testing before the programming procedure occurs. This testing procedure can allow the programming procedure to take material, and process differences into account and individualize the procedure for a single device, or a group of devices.

The invention also provides for, in another preferred embodiment, a method of programming DRAM memory cells with varying degrees of capacitive storage capabilities. The DRAM memory device can therefore store a variety of logical values depending upon the specific voltage leakage characteristics of a memory cell.

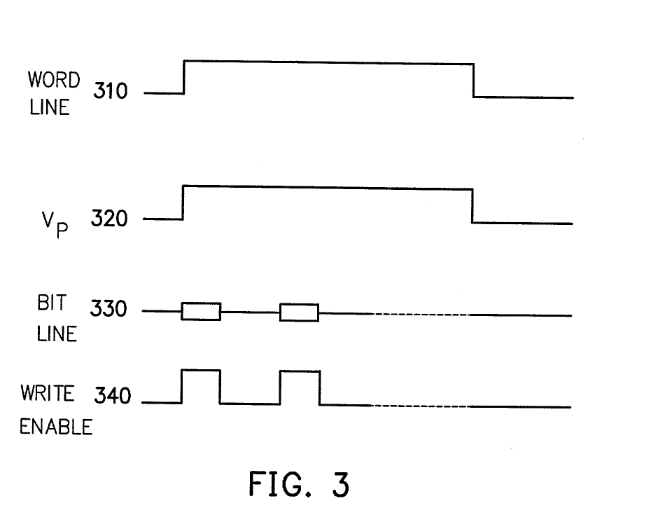

The method of programming will be described in detail as follows. FIG. 3 shows a timing diagram that exemplifies the programming method as per one embodiment of the invention. A programming voltage is applied to a first terminal of the storage capacitor 320. A word line is then brought high to activate the transistors on said wordline 310. Specific memory cells are then programmed by activating their corresponding bitline 330, and a write enable signal 340 activates to enable the programming to occur. The voltage of the bitline will typically be ground, however, it should be noted that a voltage can be applied on the bitline during the programming procedure. The program can then choose another wordline and program memory cells on that wordline and so forth.

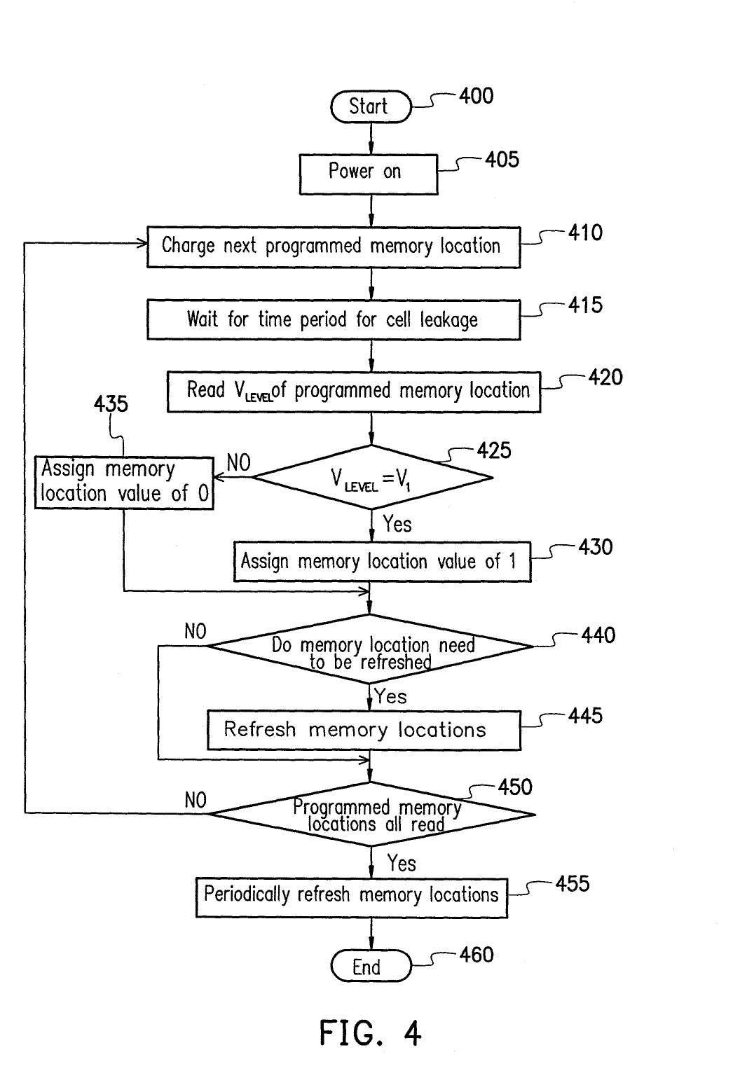

Referring to FIG. 4 shows one preferred embodiment of the invention for the reading, and operation of the programmable DRAM. In step 405 power is applied to the circuit. In step 410 the next programmed DRAM memory location is charged with a voltage. In step 415 the circuit waits for a determined amount of time for the cell to leak. A memory location that has had a programming voltage applied to it will leak current and degrade the voltage level at a greater rate than a memory location that has not had a programming voltage applied to it. In step 420 the memory locations voltage level, or V_{LEVEL} is determined. In step 425 if the memory locations V_{LEVEL} corresponds to a first predetermined voltage range (V₁) then that memory location will be assigned a logical value of 1 in step 430. If the memory locations V_{LEVEL} corresponds to a second predetermined voltage range then that memory location will be assigned a logical value of 0 in step 435. In an embodiment of the invention a sense amplifier 140 can detect the voltage level (V_{LEVEL}) and output a logical 1 or 0 depending upon a comparison between V_{LEVEL} and a reference voltage V_{REF}. Steps 440 and 445 refresh memory locations if necessary. In step 450 the circuit determines if all programmed memory locations have been read. If they all have been read then the program goes to step 455 which instructs it to periodically refresh the memory locations. If there are more memory locations to be read than the circuit returns to step 410. It should be noted that the invention allows for a testing procedure to determine the memory cell drainage time needed for an individual memory device to take into account programming, material, or process differences.

Another envisioned embodiment is the creation of a DRAM device which has an area that consists of volatile memory as is consistent with conventional DRAM devices, and an area that is programmed as disclosed in the invention. This flexible mix of programmable non-volatile memory, and regular DRAM on the same die is a very attractive memory system. A mixture of volatile, and non-volatile DRAM with other types of memory devices with accompanying circuitry, such as an EPROM can also be incorporated into a single device, as well known in the art.

Various additional modifications may be made to the illustrated embodiments without departing from the spirit and scope of the invention. Therefore, the invention lies in the claims hereinafter appended.

What is claimed is:

1. A method to program a memory device comprising the steps of:
selecting an individual memory cell to be programmed; and
applying a programming voltage to the memory cell to cause an alteration in the voltage leakage characteristics of the memory cell.

2. The method of claim 1, wherein the memory device is a DRAM.

3. The method of claim 1, wherein the programming voltage is a voltage of suitable magnitude to stress the dielectric of a capacitive storage device of a DRAM memory cell.

4. The method of claim 1, wherein the individual memory cell consists of a storage capacitor, a first bit line, a first wordline, and a transistor.

5. The method of claim 1, wherein the programming voltage is a applied by gradually increasing the voltage.

6. A method of reading a DRAM device comprising the steps of:
charging a memory cell to a first voltage;
allowing the memory cell to discharge for a given time;
determining the voltage level after a given time and assigning a value to the memory location based on the voltage level;
periodically refreshing the memory cell.

7. The method of claim 6, wherein a memory cell with a higher voltage level after a given time is assigned a logical 1, and a memory cell with a lower voltage level after a given time is assigned a logical 0.

8. The method of claim 6, wherein the said voltage level is compared to a reference voltage level.

9. A programmable DRAM comprising:
at least one memory cell with a first voltage drainage characteristic;
at least one memory cell with a second voltage drainage characteristic
wherein the second voltage drainage characteristic is the result of a purposely-altered capacitive storage capability;

10. The programmable DRAM of claim 9, wherein the memory cell consists of a storage capacitor, a first bit line, a first wordline, and a transistor.

11. The programmable DRAM of claim 9, wherein the altered capacitive storage capability is the result of a purposely applied programming voltage.

12. The applied programming voltage of claim 9, wherein the programming voltage is a voltage of suitable magnitude to stress the dielectric of a capacitive storage device of a DRAM memory cell.

13. A memory device comprising:
volatile DRAM memory cells; and
accompanying circuitry for reading and writing to volatile memory cells;
electrically programmable non-volatile DRAM memory cells comprising:
a wordline and a bit line;
a transistor;
a storage capacitor; and
accompanying circuitry for programming said non-volatile DRAM memory cells, said circuitry operable to:
program said memory cells by applying a programming voltage to the storage capacitor as to alter its storage capacitive capability; and
accompanying circuitry for reading said non-volatile DRAM memory cell, said circuitry operable to:
charge said memory cell to a voltage;
waiting for a predetermined time;
detecting the voltage level on the storage capacitor
assigning a memory cell a value based on the voltage level of the storage capacitor;
accompanying circuitry for refreshing said DRAM memory cells.

14. The memory device of claim 13, which further comprises a sense amplifier to detect the voltage level on the storage capacitor.

15. The sense amplifier of claim 14, which further comprises a reference voltage in order to assign a memory cell a value based on the voltage level.

16. The memory device of claim 13, wherein the memory device is also composed of mask ROM memory cells and accompanying circuitry.

17. The memory device of claim 13, wherein the memory device is also composed of EPROM memory cells and accompanying circuitry.

18. A memory device comprising:
at least one electrically programmable non-volatile DRAM memory cell comprising:
a wordline and a bit line;
a transistor;
a storage capacitor;
accompanying circuitry for programming said DRAM memory cell, said circuitry operable to:
program said memory cell by applying a programming voltage to the storage capacitor as to alter its storage capacitive capability.
accompanying circuitry for reading said DRAM memory cell, said circuitry operable to:
charge said memory cell to a voltage;
waiting for a predetermined time;
detecting the voltage level on the storage capacitor;
assigning a memory cell a value based on the voltage level of the storage capacitor.

19. The memory device of claim 18, wherein the memory device is also composed of volatile DRAM memory cells and accompanying circuitry.

20. The memory device of claim 18, which further comprises a sense amplifier to detect the voltage level on the storage capacitor.

21. The sense amplifier of claim 20, which further comprises a reference voltage in order to assign a memory cell a value based on the voltage level.

22. The memory device of claim 18, wherein the memory device is also composed of mask ROM memory cells and accompanying circuitry.

23. The memory device of claim 18, wherein the memory device is also composed of EPROM memory cells and accompanying circuitry.
